(19) United States
(12) Patent Application Publication
(10) Pub. No.: US 2006/0181851 A1
(43) Pub. Date: Aug. 17, 2006

(54) Heatsink structure with an air duct

(76) Inventors: Wang Frank, Taipei (TW); Lin Chun-Lung, Taipei (TW)

Correspondence Address: GENUS LAW GROUP;LOWE HAUPTMAN & BERNER, LLP, 1700 DIAGONAL ROAD, SUITE 300, ALEXANDRIA, VA, 22314, US

(21) Appl. No.: 11/058,044

(22) Filed: Feb. 15, 2005

(51) Int. Cl. H05K 7/20

(52) U.S. Cl. 361/700

(57) ABSTRACT

The present invention provides a heatsink structure with an air duct, which is utilized to dissipate heat from heat-generating elements. The heatsink structure comprises a heatsink module, an air duct, and a fan module, wherein the cooling wind generated by the fan module is guided through the air duct toward the heatsink module to dissipate the heat therefrom. Via the design of the air duct of the present invention, not only the fast assembling and disassembling of the heatsink module can be achieved, but the efficiency or the cost of the installing, maintaining and changing for upgrade of the CPU and the video chipset can also be promoted or reduced.

### BACKGROUND OF THE INVENTION

1. Field of the Invention

The present invention relates to an improved heatsink structure of electronic devices, particularly to a heatsink structure with an air duct.

2. Description of the Related Art

With continuous upgrade in the operational function and speed of the central processing unit (CPU) or the video chipset of a computer, those electronic elements will generate high temperature inside the elements during the operation. However, each electronic element has its temperature limitation, and the high temperature not only will reduce the working efficiency of the electronic element, but also may induce damage or burnout of the electronic element. Accordingly, the solution of the heat-dissipating problem becomes an indispensable step in the product design of a computer. In order to let the computer may work at a normal temperature, a heatsink has been an indispensable component in a notebook computer.

Referring to FIG. 1 a perspective view of a conventional heatsink device, it comprises a heat conduction module and a fan module. The heat conduction module includes a thermal pad, a thermal conductor, and a fin set. The fan module includes a fan and a casing. Via the thermal pad, heat generated from the elements (i.e. a CPU or a video chipset, etc.) is conducted through the thermal conductor (i.e. a heat pipe) to the fin set. Because the fin set is constructed with a plurality of parallel fins, the radiate area can be increased. Exchange of heat occurs between the fin set and cooling wind generated by means of the fin module and the heat can be expelled from the computer in order to achieve cooling objectives.

Usually, the heatsink module is positioned beside the CPU unit or the video chipset, and the thermal pad needs to be closely attached to the surface of the CPU or the video chipset in order to perform the thermally-conducting function. The heatsink module needs to be tightly engaged with the fan module so that the cooling wind generated by the fan module could have heat exchange with the heatsink module. However, the aforementioned engaging manner results in the complexity of the disassembling and assembling while the CPU or video chipset is installed, maintained, or changed for upgrade.

In the conventional technology, as the heatsink module is closely attached to the surface of the CPU or the video chipset, the heatsink module has to be removed before the CPU or the video chipset is installed, maintained, or changed for upgrade. In addition, as the heatsink module is tightly engaged with the fan module for the air-tight therebetween, the fan module needs to be firstly removed before the disassembling of the heatsink module. Relatively, when installing, maintaining or changing for upgrade is completed, the heatsink module should be assembled firstly, and then the fan module is assembled, in the reverse steps as mentioned above. Thus, the conventional heatsink structure results in the complexity of the disassembling and assembling steps, the low efficiency, cost waste and the loss of components on the disassembling and assembling.

In the current market, the notebook computer is often required to be delivered in an empty machine by customers (i.e. the primary elements, such as CPU and video chipset, etc., will not be assembled inside the notebook computer). When the notebook computer has been delivered to the customer, the customer will assemble it by himself. Further, as the rapid progress of the CPU, an upgrade for CPU is often needed. Thus, for all those problems mentioned above, the present invention provides an improved heatsink.

### SUMMARY OF THE INVENTION

An object of the present invention is to improve the conventional heatsink device, wherein the engaging manner between the heatsink module and the fan module is improved to enable the installing, maintaining, and changing for upgrade of a CPU or video chipset, etc. to be simpler, more efficient, and of less loss without expending any heat-dissipating efficiency.

The present invention is a heatsink structure with an air duct, which is utilized to dissipate the heat generated by a heat-generating element. The invention comprises a heatsink module, an air duct, and a fan module. The heatsink module includes a thermal pad, a thermal conductor, and a fin set; the thermal pad is closely attached to the heat-generating element. The air duct is a cover-like structure and having at least a first opening and a second opening; the first opening is air-tightly engaged with the outer periphery of the fin set. The exhaust opening of the fan module is air-tightly engaged with the second opening of the air duct; wherein the fan module, the air duct, and the fin set of the heatsink module are jointly to form a heat-dissipating air duct.

The present invention provides a heatsink device with an air duct positioned between the heatsink module and the fan module. The air duct is a cover-like structure engaged with the heatsink module and the fan module and may be made of a plastic material to possess the characteristics of simple structure, light weight, easy disassembling and assembling, etc. The air duct can interconnect and be air-tightly engaged with the heatsink module and the fan module in order that the cooling wind generated by the fan could be completely sent to the heatsink module to have a heat exchange with the fin set of the heatsink module. When a CPU or video chipset is assembled, maintained, or changed for upgrade, one only needs to remove the air duct before the disassembling of the heatsink module. Thus, in the present invention, the assembling, maintaining, and changing for upgrade of a CPU or video chipset can be simple and quick without disassembling and assembling fan module.

The present invention has the following benefits:
1. Via practicing the present invention, one can simply and quickly install, maintain, and change for upgrading a CPU or video chipset without disassembling and assembling the fan module.
2. The procedure of the present invention for installing, maintaining, and changing for upgrading a CPU or video chipset is simple, so the efficiency of operations can be increased and the cost can be reduced.
3. The present invention can reduce the loss of elements during disassemble and assemble procedure.

To clarify the characteristics, objectives, and functions of the present invention, the related embodiments, referring to the appended drawings, are described below.

### BRIEF DESCRIPTION OF THE DRAWINGS

FIG. 1 is a perspective view of a conventional heatsink device;

FIG. 2 is a perspective view of one embodiment of the present invention;

FIG. 3 is an exploded perspective view of one embodiment of the present invention;

FIG. 4 is a perspective view of the heatsink module of one embodiment of the present invention;

FIG. 5 is a sectional view of one embodiment of the present invention along the line B-B in FIG. 2;

FIG. 6 is a perspective view of the air duct of one embodiment of the present invention;

FIG. 7 is an exploded view of the fan module of one embodiment of the present invention; and

FIG. 8 is a sectional view of one embodiment of the present invention along the line A-A in FIG. 2.

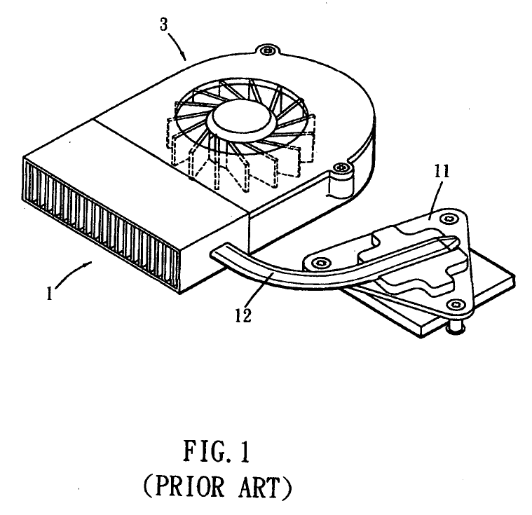

### DETAILED DESCRIPTION OF THE INVENTION

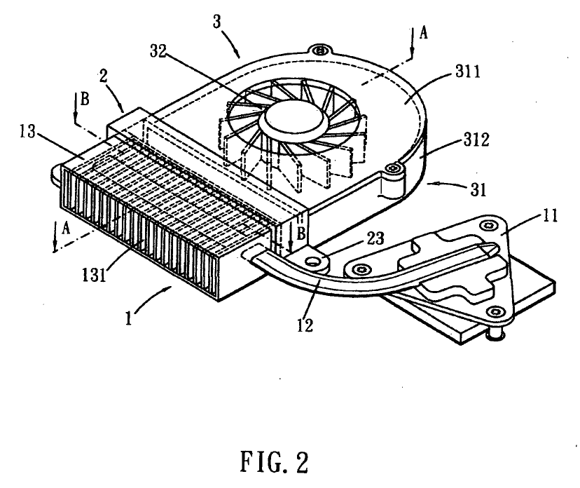

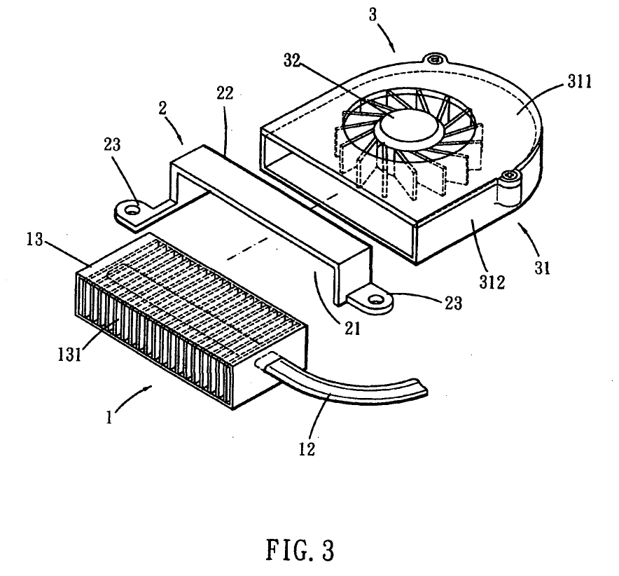

Referring to FIG. 2 and FIG. 3 separately a perspective view and an exploded perspective view of one embodiment of the present invention, the present invention is a heatsink structure with an air duct, utilized in an electronic device, particularly in the electronic devices of a notebook computer to dissipate heat from heat-generating elements, such as CPU or video chipset, etc. The heatsink structure with an air duct of the present invention comprises a heatsink module 1, an air duct 2, and a fan module 3.

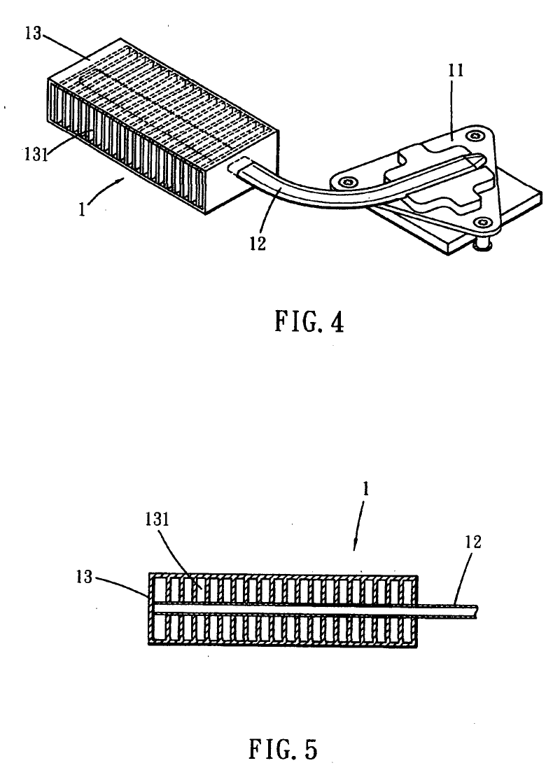

Referring to FIG. 4 and FIG. 5 separately a perspective view of the heatsink module of one embodiment of the present invention and a sectional view along the line B-B in FIG. 2, the heatsink module 1 includes a thermal pad 11, a thermal conductor 12, and a fin set 13. The thermal pad 11 is of a planar shape and has about the same area as the surface of heat-generating elements. The primary function of the thermal pad 11 is to conduct the heat generated by heat-generating elements out of the elements via surface contact. The thermal conductor 12 is a heat pipe and of a strip shape. One end of the thermal conductor 12 is engaged with thermal pad 11 for thermally-conductive. The primary function of the thermal conductor 12 is to transfer the heat conducted by thermal pad 11 to the fin set 13. The fin set 13 comprises a plurality of parallel fins 131, which are vertical on the thermal conductor 12 and each fin 131 is of a sheet shape; another end of the thermal conductor 12 intersects each fin 131 at its center and is also engaged with each fin 131 for thermally-conductive. This kind of engagement method averages the distance of heat-transferring. Via the surface's expanding of the fin set 13, the heat conducted by the thermal conductor 12 can be effectively distributed and expanded. As the primary function of heatsink module 1 is to conduct, transfer, and dissipate the heat, the heatsink is made of heat resistance and thermal conductivity material, such as copper or aluminum metal in one embodiment of the present invention.

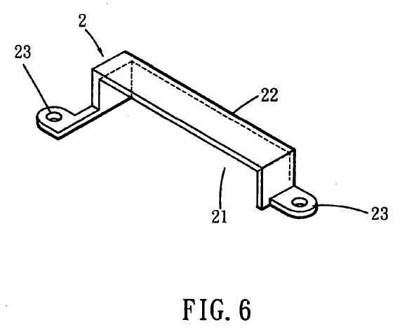

Referring to FIG. 6 a perspective view of the air duct of one embodiment of the present invention, the air duct 2 is a cover-like structure of a U shape, and at least has a first opening 21 and a second opening 22 positioned separately at the front and the rear side thereof. The first opening 21 is air-tightly engaged with the outer periphery of the fin set 13. At least one lateral side of the air duct 2 has a fixing portion 23, which is a fixing lug possessing a threaded hole at the center thereof. The air duct 2 can be made of a plastic material, and has characteristics of simple structure, lightweight, easy disassembling and assembling, etc.

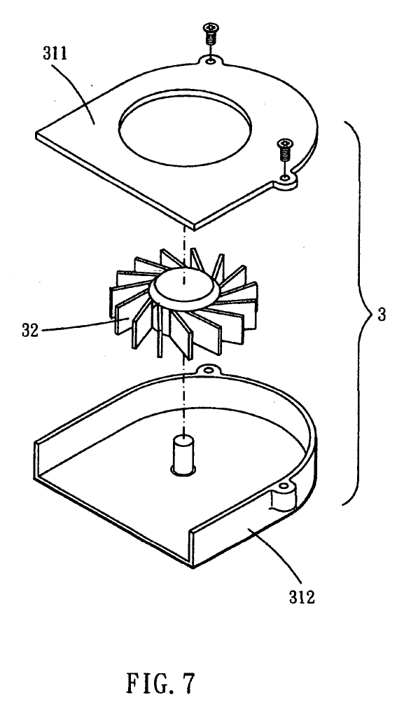

Referring to FIG. 7 an exploded view of the fan module of one embodiment of the present invention, the fan module 3 comprises a casing 31 and a fan 32. The casing 31 includes an upper covering plate 311 and a lower casing 312. The upper covering plate 311 has an intake at the intake portion of the fan 32 in order to provide air for the fan 32. The lower casing 312 includes a planar board and a vertical wall projecting upward from the periphery of the planar board and there is a gap at the joint portion of the vertical wall and the air duct 2. Via a screw-fixing, the upper covering plate 311 and the lower casing 312 are combined and form an air chamber. In addition, after combining, the gap and the upper covering plate 311 form an exhaust opening 33. The exhaust opening 33 is air-tightly engaged with the second opening 22 of the air duct 2. The fan 32 is installed inside the casing 31 and generates cooling winds.

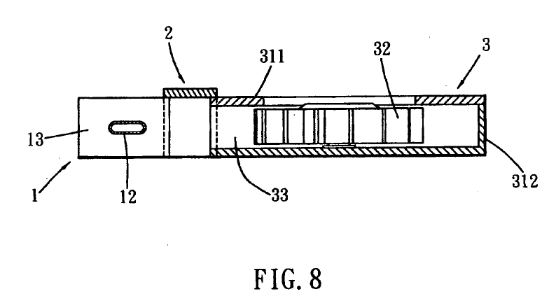

Referring to FIG. 8 a sectional view along the line A-A in FIG. 2, while practicing the present embodiment, the heatsink module 1 and the fan module 3 can be assembled firstly, and then the air duct 2 hoods downward to be engaged separately with the outer periphery of the fin set 13 and the exhaust opening 33 of the fan module 3. Via the air-tight engagement of the air duct 2, the fan module 3, the air duct 2, and the fin set 13 jointly form a complete heat-dissipating air duct.

Via practicing the present invention, one can only need to remove the air dust 2 and then assemble or disassemble of the heatsink module 1 while installing, maintaining, and changing for upgrade of a CPU or video chipset is undertaken. Thus, the present invention has an obvious improvement in comparison with the conventional technology.

Those described above are only the preferred embodiments of the present invention, and it is not intended to limit the scope of the present invention. Any equivalent variation and modification according to the appended claims of the present invention would not depart from the spirit of the present invention and is to be included within the scope of the present invention.

What is claimed is:

1. A heatsink structure with an air duct, utilized to dissipate the heat generated by heat-generating elements in an electronic device, comprising:
a heatsink module, which further includes a thermal pad, a thermal conductor, and a fin set, with said thermal pad closely attached to the heat-generating element;
an air duct, which is a cover-like structure and possesses at least a first opening and a second opening, with said first opening air-tightly engaged with the outer periphery of said fin set; and
a fan module, whose exhaust opening is air-tightly engaged with said second opening;
wherein said fan module, said air duct, and said fin set jointly form a heat-dissipating air duct.

2. The heatsink structure with an air duct according to claim 1, wherein said thermal pad is of a planar shape.

3. The heatsink structure with an air duct according to claim 1, wherein said thermal conductor is a heat pipe.

4. The heatsink structure with an air duct according to claim 1, wherein said fin set comprises a plurality of parallel fins which are vertical on said thermal conductor.

5. The heatsink structure with an air duct according to claim 4, wherein said fins are of a sheet shape.

6. The heatsink structure with an air duct according to claim 1, wherein one end of said thermal conductor is engaged with said thermal pad, and another end of said thermal conductor intersects said fin set at its center and is engaged with said fin set for thermally-conductive.

7. The heatsink structure with an air duct according to claim 1, wherein said heatsink module is made of heat resistance and thermal conductivity material.

8. The heatsink structure with an air duct according to claim 1 or claim 7, wherein said heatsink module is made of a copper metal or an aluminum metal.

9. The heatsink structure with an air duct according to claim 1, wherein said air duct is of a U shape.

10. The heatsink structure with an air duct according to claim 1, wherein said air duct is made of a plastic material.

11. The heatsink structure with an air duct according to claim 1, wherein said air duct at least has a fixing portion in one lateral side.

12. The heatsink structure with an air duct according to claim 11, wherein said fixing portion is a fixing lug with a threaded hole positioned at its center.

13. The heatsink structure with an air duct according to claim 1, wherein said fan module further includes a casing and a fan.

14. The heatsink structure with an air duct according to claim 13, wherein said casing further includes an upper covering plate and a lower casing.

15. The heatsink structure with an air duct according to claim 14, wherein said upper covering plate has an intake positioned at the intake portion of said fan.

16. The heatsink structure with an air duct according to claim 14, wherein said lower casing includes a planar board and a vertical wall projecting upward from the periphery of said planar board with a gap at the joint portion of said vertical and said air duct.

17. The heatsink structure with an air duct according to claim 16, wherein via a screw-fixing of combining, said upper covering plate and said lower casing form an air chamber, and after said combining, said gap and said upper covering plate form an exhaust opening.

18. The heatsink structure with an air duct according to claim 13, wherein said fan is installed fixedly inside said casing.

19. The heatsink structure with an air duct according to claim 1, wherein said air duct hoods downward to be engaged separately with the outer periphery of said set of heatsink fins and said exhaust opening of said fan module.
